(19) United States
(12) Patent Application Publication
(10) Pub. No.: US 2026/0013171 A1
(43) Pub. Date: Jan. 8, 2026

(54) NITRIDE SEMICONDUCTOR DEVICE AND FABRICATION METHOD THEREOF

(71) Applicant: Panasonic Holdings Corporation, Osaka (JP)

(72) Inventors: Masahiro OGAWA, Osaka (JP); Naoki Torii, Osaka (JP); Satoshi Tamura, Osaka (JP)

(21) Appl. No.: 19/327,025

(22) Filed: Sep. 12, 2025

Related U.S. Application Data
(63) Continuation of application No. PCT/JP2023/040498, filed on Nov. 10, 2023.

(30) Foreign Application Priority Data
Mar. 31, 2023 (JP) 2023-058167

(51) Int. Cl. H10D 30/47; H10D 30/01; H10D 62/10; H10D 62/824; H10D 64/27

(52) U.S. Cl. CPC H10D 30/477; H10D 30/015; H10D 30/475; H10D 62/125; H10D 62/824; H10D 64/411

(57) ABSTRACT

A nitride semiconductor device includes: a substrate; a first nitride semiconductor layer provided above the substrate; a second nitride semiconductor layer of p-type conductivity provided above the first nitride semiconductor layer; a third nitride semiconductor layer and a fourth nitride semiconductor layer that are provided along the inner surface of a first opening and at a portion that is outside the first opening and above the second nitride semiconductor layer, the first opening passing through the second nitride semiconductor layer; a gate electrode; a source electrode; and a drain electrode. The third nitride semiconductor layer includes: a bottom portion provided along the bottom surface of the first opening; and an outer edge portion provided outside the first opening. The layer thickness of the bottom portion is less than the layer thickness of the outer edge portion.

### CROSS REFERENCE TO RELATED APPLICATIONS

This is a continuation application of PCT International Patent Application No. PCT/JP2023/040498 filed on Nov. 10, 2023, designating the United States of America, which is based on and claims priority of Japanese Patent Application No. 2023-058167 filed on Mar. 31, 2023. The entire disclosures of the above-identified applications, including the specifications, drawings and claims are incorporated herein by reference in their entirety.

### FIELD

The present disclosure relates to a nitride semiconductor device and a fabrication method thereof.

### BACKGROUND

Nitride semiconductors such as gallium nitride (GaN) are wide-gap semiconductors having large band gaps, and have the properties of a large breakdown field and a high saturation drift velocity of electrons in comparison with that of gallium arsenide (GaAs) semiconductors or silicon (Si) semiconductors, for example. Thus, power transistors using nitride semiconductors beneficial for higher output and withstand voltage are currently under research and development.

For instance, Patent Literature (PTL) 1 discloses a semiconductor device including a GaN-based layered structure. The semiconductor device disclosed in PTL 1 is a vertical field-effect transistor (FET) including (i) a regrowth layer positioned to cover an opening formed in the GaN-based layered structure and including an electron transit layer and an electron supply layer and (ii) a gate electrode formed along and on the regrowth layer. Two-dimensional electron gas (2DEG) generated in the regrowth layer forms a channel, which achieves the FET having high electron mobility and low on-resistance.

### CITATION LIST

### Patent Literature

PTL 1: International Publication No. WO2015/122135

### SUMMARY

### Technical Problem

In a vertical field-effect transistor (FET), an electron transit layer at the bottom of an opening may be thick, which may increase the resistance value.

In view of this, the present disclosure provides a nitride semiconductor device capable of decreasing on-resistance, and a fabrication method thereof.

### Solution to Problem

To solve the above issue, a nitride semiconductor device according to one aspect of the present disclosure includes: a substrate; a first nitride semiconductor layer provided above the substrate; a second nitride semiconductor layer of p-type conductivity provided above the first nitride semiconductor layer; a third nitride semiconductor layer and a fourth nitride semiconductor layer that are provided along an inner surface of a first opening and at a portion that is outside the first opening and above the second nitride semiconductor layer, the third nitride semiconductor layer and the fourth nitride semiconductor layer being provided in stated order from a side on which the substrate is present, the first opening passing through the second nitride semiconductor layer and reaching the first nitride semiconductor layer; a gate electrode provided above the fourth nitride semiconductor layer; a source electrode spaced apart from the gate electrode; and a drain electrode provided on an opposite side of the substrate from the first nitride semiconductor layer, in which the third nitride semiconductor layer includes: a bottom portion provided along a bottom surface of the first opening; and an outer edge portion provided outside the first opening, and a layer thickness of the bottom portion in a direction perpendicular to a main surface of the substrate is less than a layer thickness of the outer edge portion in the direction perpendicular to the main surface.

A fabrication method for fabricating a nitride semiconductor device according to another aspect of the present disclosure includes: a process of forming a first nitride semiconductor layer and a second nitride semiconductor layer of p-type conductivity above a substrate in stated order; a process of forming a first opening passing through the second nitride semiconductor layer and reaching the first nitride semiconductor layer; a process of forming a third nitride semiconductor layer and a fourth nitride semiconductor layer in stated order along an inner surface of the first opening and at a portion that is outside the first opening and above the second nitride semiconductor layer; a process of forming a gate electrode above the fourth nitride semiconductor layer; a process of forming a source electrode at a position apart from the gate electrode; and a process of forming a drain electrode on an opposite side of the substrate from the first nitride semiconductor layer, in which in the process of forming the third nitride semiconductor layer, the third nitride semiconductor layer is formed by epitaxial growth under a condition that facilitates growth more in a direction parallel to a main surface of the substrate than in a direction perpendicular to the main surface.

### Advantageous Effects

The present disclosure can provide a nitride semiconductor device with low on-resistance and a fabrication method thereof.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a plan view illustrating a plan view layout of a nitride semiconductor device according to an embodiment.

FIG. 2 is a cross-sectional view of the nitride semiconductor device according to the embodiment.

FIG. 3 is a partially enlarged cross-sectional view of FIG. 2.

FIG. 4A is a cross-sectional view illustrating a nitride semiconductor layering process in a fabrication method for fabricating the nitride semiconductor device according to the embodiment.

FIG. 4B is a cross-sectional view illustrating a resist patterning process in the fabrication method for fabricating the nitride semiconductor device according to the embodiment.

FIG. 4C is a cross-sectional view illustrating a gate opening formation process in the fabrication method for fabricating the nitride semiconductor device according to the embodiment.

FIG. 4D is a cross-sectional view illustrating a nitride semiconductor regrowth process in the fabrication method for fabricating the nitride semiconductor device according to the embodiment.

FIG. 4E is a cross-sectional view illustrating a gate electrode formation process in the fabrication method for fabricating the nitride semiconductor device according to the embodiment.

FIG. 4F is a cross-sectional view illustrating a source electrode formation process in the fabrication method for fabricating the nitride semiconductor device according to the embodiment.

FIG. 5 is a cross-sectional view of a nitride semiconductor device according to a variation of the embodiment.

### DESCRIPTION OF EMBODIMENTS

### Overview of the Present Disclosure

A nitride semiconductor device according to a first aspect of the present disclosure includes: a substrate; a first nitride semiconductor layer provided above the substrate; a second nitride semiconductor layer of p-type conductivity provided above the first nitride semiconductor layer; a third nitride semiconductor layer and a fourth nitride semiconductor layer that are provided along an inner surface of a first opening and at a portion that is outside the first opening and above the second nitride semiconductor layer, the third nitride semiconductor layer and the fourth nitride semiconductor layer being provided in stated order from a side on which the substrate is present, the first opening passing through the second nitride semiconductor layer and reaching the first nitride semiconductor layer; a gate electrode provided above the fourth nitride semiconductor layer; a source electrode spaced apart from the gate electrode; and a drain electrode provided on an opposite side of the substrate from the first nitride semiconductor layer, in which the third nitride semiconductor layer includes: a bottom portion provided along a bottom surface of the first opening; and an outer edge portion provided outside the first opening, and a layer thickness of the bottom portion in a direction perpendicular to a main surface of the substrate is less than a layer thickness of the outer edge portion in the direction perpendicular to the main surface.

Thus, on-resistance can be decreased by decreasing the layer thickness of the bottom portion of the third nitride semiconductor layer provided along the bottom surface of the first opening through which a current between the source and the drain flows. Accordingly, a nitride semiconductor device with low on-resistance can be achieved with the first aspect.

Moreover, a nitride semiconductor device according to a second aspect of the present disclosure is the nitride semiconductor device according to the first aspect in which the third nitride semiconductor layer includes a side wall portion provided along a side wall surface of the first opening, and a layer thickness of the side wall portion in a direction parallel to the main surface is greater than the layer thickness of the outer edge portion in the direction perpendicular to the main surface.

Thus, the distance between the side wall portion of the third nitride semiconductor layer and the second nitride semiconductor layer of the p-type conductivity is increased, which can suppress the carrier concentration of the third nitride semiconductor layer from decreasing. Thus, it is possible to decrease the on-resistance of the nitride semiconductor device.

Moreover, a nitride semiconductor device according to a third aspect of the present disclosure is the nitride semiconductor device according to the first or second aspect that includes a fifth nitride semiconductor layer of the p-type conductivity provided between the gate electrode and the fourth nitride semiconductor layer.

Thus, the fifth nitride semiconductor layer can decrease the carrier concentration directly below the gate electrode, which can cause the threshold voltage of the nitride semiconductor device to shift to the positive side. Accordingly, the nitride semiconductor device according to the third aspect can be achieved as a normally-off FET.

Moreover, a nitride semiconductor device according to a fourth aspect of the present disclosure is the nitride semiconductor device according to one of the first to third aspects in which at a position apart from the gate electrode, the source electrode is provided inside a second opening passing through the fourth nitride semiconductor layer and the third nitride semiconductor layer and reaching the second nitride semiconductor layer.

Thus, because of the voltage applied between the source electrode and the drain electrode, a depletion layer can be formed near the interface between the second nitride semiconductor layer and the first nitride semiconductor layer. Since the depletion layer is formed, it is possible to suppress the occurrence of a leakage current between the source and the drain. Accordingly, the withstand voltage of the nitride semiconductor device can be increased.

Moreover, a nitride semiconductor device according to a fifth aspect of the present disclosure is the nitride semiconductor device according to one of the first to fourth aspects in which in a plan view of the substrate, a distance between an end of the gate electrode and the source electrode is less than a distance between an end of the first opening and the source electrode.

Thus, it is possible to enhance the controllability of a channel formed in a regrowth layer.

A fabrication method for fabricating a nitride semiconductor device according to a sixth aspect of the present disclosure includes: a process of forming a first nitride semiconductor layer and a second nitride semiconductor layer of p-type conductivity above a substrate in stated order; a process of forming a first opening passing through the second nitride semiconductor layer and reaching the first nitride semiconductor layer; a process of forming a third nitride semiconductor layer and a fourth nitride semiconductor layer in stated order along an inner surface of the first opening and at a portion that is outside the first opening and above the second nitride semiconductor layer; a process of forming a gate electrode above the fourth nitride semiconductor layer; a process of forming a source electrode at a position apart from the gate electrode; and a process of forming a drain electrode on an opposite side of the substrate from the first nitride semiconductor layer, in which in the process of forming the third nitride semiconductor layer, the third nitride semiconductor layer is formed by epitaxial growth under a condition that facilitates growth more in a direction parallel to a main surface of the substrate than in a direction perpendicular to the main surface.

Thus, it is possible to make the bottom portion of the third nitride semiconductor layer provided along the bottom surface of the first opening have a thin layer thickness. As such, it is possible to fabricate a nitride semiconductor device with low on-resistance.

A fabrication method for fabricating a nitride semiconductor device according to a seventh aspect of the present disclosure is the fabrication method according to the sixth aspect in which the condition includes that a film formation temperature is higher than or equal to 1100 degrees Celsius.

Thus, it is possible to make the bottom portion of the third nitride semiconductor layer provided along the bottom surface of the first opening have a thin layer thickness. As such, it is possible to fabricate a nitride semiconductor device with low on-resistance.

A fabrication method for fabricating a nitride semiconductor device according to an eighth aspect of the present disclosure is the fabrication method according to the sixth or seventh aspect in which the condition includes that a V/III ratio of feed materials is greater than or equal to 1000.

Thus, it is possible to make the bottom portion of the third nitride semiconductor layer provided along the bottom surface of the first opening have a thin layer thickness. As such, it is possible to fabricate a nitride semiconductor device with low on-resistance.

Hereinafter, an embodiment of the present disclosure is described with reference to the drawings.

It should be noted that the embodiments described below each indicate a general or specific example. The numerical values, shapes, materials, constituent elements, arrangement and connection of the constituent elements, steps, order of steps, and other details indicated in the embodiments described below are merely examples, and do not intend to limit the present disclosure. Moreover, the constituent elements not recited in the independent claims, among those described in the embodiments below are described as optional constituent elements.

Moreover, the figures are schematic illustrations and are not necessarily precise depictions. Accordingly, for instance, scales used in the figures need not necessarily be the same. Moreover, in the figures, substantially the same elements are assigned the same reference signs, and overlapping explanations are omitted or simplified.

Moreover, in the specification, terms indicating relationships between elements such as parallel or orthogonal, terms describing the shapes of elements such as rectangular or trapezoidal, and a numerical value range are not expressions indicating only strict meanings but expressions intended to include practically equivalent ranges, that is, a difference of around several percentages, for example.

Moreover, in the specification and figures, the X-axis, the Y-axis, and the Z-axis indicate three axes in a three-dimensional orthogonal coordinate system. When a substrate is rectangular in a plan view, the X-axis and the Y-axis respectively correspond to a direction parallel to a first side of a rectangle and a direction parallel to a second side and orthogonal to the first side. The Z-axis corresponds to a thickness direction of the substrate. It should be noted that in the specification, the thickness direction of the substrate is a direction perpendicular to a main surface of the substrate. The thickness direction is the same as a direction in which semiconductor layers are layered, and is also referred to as a vertical direction. Moreover, a direction parallel to the main surface of the substrate may be referred to as a horizontal direction.

Moreover, the side on which a gate electrode and a source electrode are provided (the positive side of the Z-axis) relative to the substrate is regarded as above or the upper side, and the side on which a drain electrode is provided (the negative side of the Z-axis) relative to the substrate is regarded as below or the lower side.

Moreover, in the specification, the terms, above and below do not indicate the upward direction (vertically upward) and the downward direction (vertically downward) in absolute spatial recognition, and are used as terms defined by the relative positional relationship based on the layered order in a layered configuration. Moreover, the terms, above and below are used not only in the case where a constituent element is present between two constituent elements spaced apart from each other, but also in the case where two constituent elements are so disposed as to be tightly in contact with each other.

Moreover, in the specification, unless otherwise noted, the term, in a/the plan view means that a nitride semiconductor device is viewed in a direction perpendicular to a main surface of the substrate of the nitride semiconductor device, that is, the main surface of the substrate is viewed from front.

Moreover, in the specification, unless otherwise noted, ordinal numbers such as first and second do not indicate the number or order of constituent elements, but are used to avoid the mix-up of constituent elements of the same kind and distinguish one from another.

### Embodiment

### [Configuration]

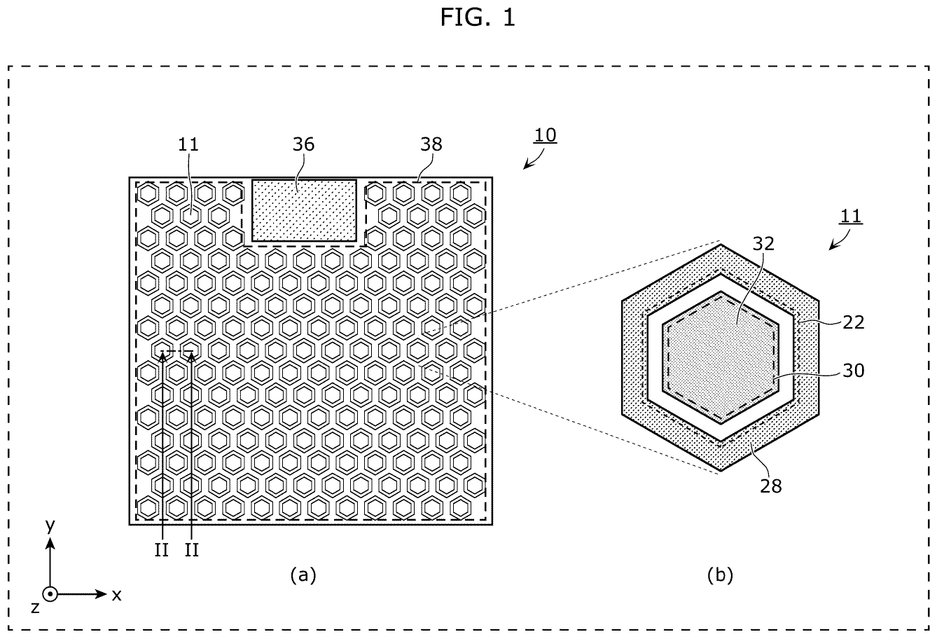

First, a configuration of a nitride semiconductor device according to an embodiment is described with reference to FIGS. 1 to 3.

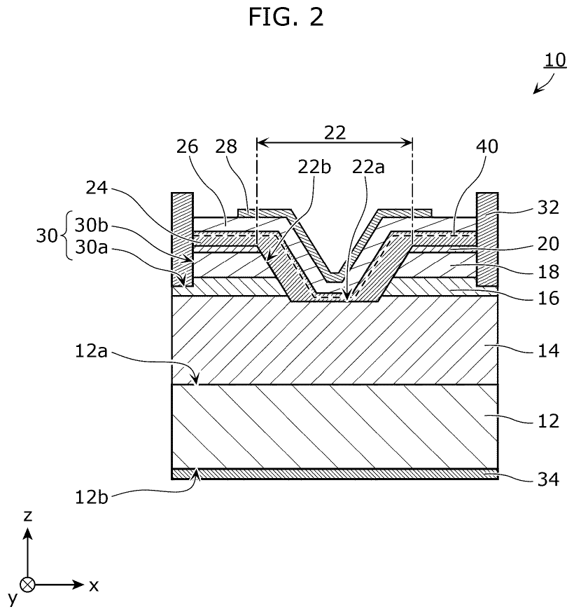

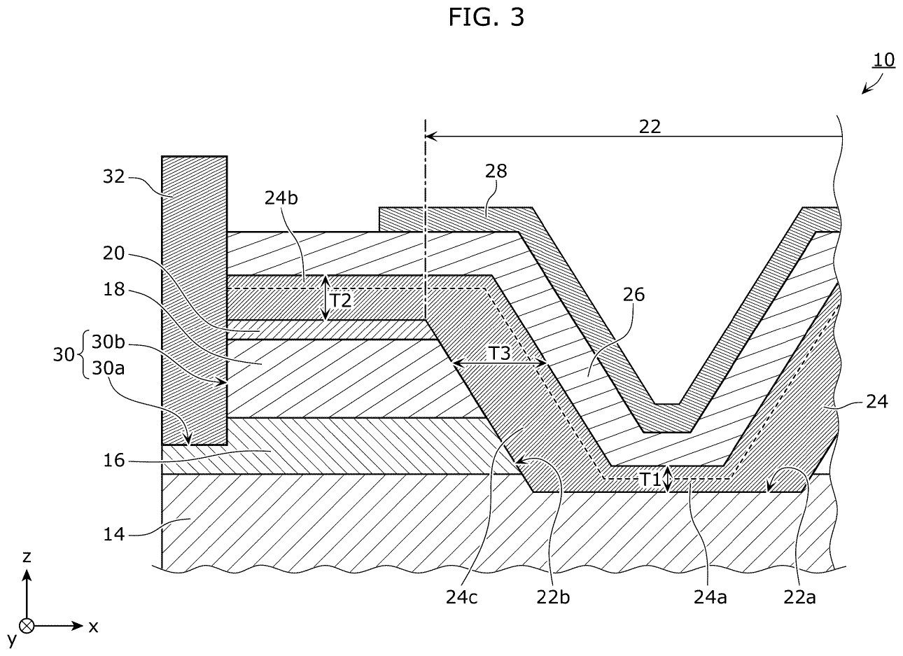

FIG. 1 is a plan view illustrating a plan view layout of nitride semiconductor device 10 according to the embodiment. FIG. 2 is a cross-sectional view of nitride semiconductor device 10 according to the embodiment. FIG. 3 is a partially enlarged cross-sectional view of FIG. 2. Specifically, FIG. 3 is a partially enlarged illustration of electron transit layer 24 in FIG. 2.

Here, (a) in FIG. 1 is a plan view when nitride semiconductor device 10 is viewed from above. (b) in FIG. 1 is an enlarged illustration of unit cell 11 of nitride semiconductor device 10. FIG. 2 illustrates a cross section of nitride semiconductor device 10 according to the embodiment through line II-II in FIG. 1.

As illustrated in (a) in FIG. 1, nitride semiconductor device 10 includes a plurality of unit cells 11. The plurality of unit cells 11 are arranged two-dimensionally. Each of the plurality of unit cells 11 has the same configuration. Each unit cell 11 is hexagonal in a plan view. In the plan view, the plurality of unit cells 11 are so arranged that the centers of the plurality of unit cells 11 are at the vertices of regular triangles in a packing arrangement.

Unit cell 11 is configured by having source electrode 32 as the center. FIG. 2 illustrates a cross section through line II-II passing through the centers of two adjacent unit cells 11.

In the embodiment, nitride semiconductor device 10 is a device having a layered structure of semiconductor layers containing, as main components, nitride semiconductors such as GaN and AlGaN. Specifically, nitride semiconductor device 10 has a heterostructure of an AlGaN film and a GaN film.

In the heterostructure of the AlGaN film and the GaN film, spontaneous polarization or piezoelectric polarization on a c-plane referred to as the (0001) plane generates high-concentration two-dimensional electron gas (2DEG) 40 on the heterointerface. Thus, even in an undoped state, nitride semiconductor device 10 has the feature of a sheet carrier concentration higher than or equal to 1×10¹³ cm⁻² being obtained on the heterointerface.

As illustrated in FIG. 2, nitride semiconductor device 10 includes substrate 12, drift layer 14, first underlayer 16, second underlayer 18, third underlayer 20, gate opening 22, electron transit layer 24, electron supply layer 26, gate electrode 28, source opening 30, source electrode 32, and drain electrode 34. Furthermore, as illustrated in (a) in FIG. 1, nitride semiconductor device 10 includes gate electrode pad 36 and source electrode pad 38. It should be noted that in (a) in FIG. 1, the contour of source electrode pad 38 is schematically indicated by the dashed line.

Hereinafter, the constituent elements of nitride semiconductor device 10 are described in detail.

Substrate 12 is made of a nitride semiconductor and includes first main surface 12a and second main surface 12b opposite to each other. First main surface 12a is the main surface on the side where drift layer 14 is formed. Specifically, first main surface 12a approximately corresponds to the c-plane. Second main surface 12b is the main surface on the side where drain electrode 34 is formed.

Substrate 12 is, for example, an n-type GaN substrate having a thickness of 300 μm and a carrier concentration of 1×10¹⁸ cm⁻³. It should be noted that n-type and p-type indicate semiconductor conductivity types. In the embodiment, n-type is an example of a first conductivity type of a nitride semiconductor. P-type is an example of a second conductivity type with a polarity different from that of the first conductivity type.

Moreover, substrate 12 need not be a nitride semiconductor substrate. Substrate 12 may be, for example, a silicon (Si) substrate, a silicon carbide (SiC) substrate, or zinc oxide (ZnO) substrate.

Drift layer 14 is an example of an n-type first nitride semiconductor layer provided above first main surface 12a of substrate 12. For instance, drift layer 14 is an n-type GaN film having a thickness of 8 μm and a carrier concentration of 1×10¹⁶ cm⁻³. Drift layer 14 is provided in contact with first main surface 12a of substrate 12.

First underlayer 16 is an example of a p-type second nitride semiconductor layer provided above drift layer 14. First underlayer 16 is, for example, a p-type GaN film having a thickness of 400 nm and a carrier concentration of 1×10¹⁷ cm⁻³. First underlayer 16 is provided in contact with the top surface of drift layer 14.

First underlayer 16 suppresses a leakage current between source electrode 32 and drain electrode 34. When for instance a reverse voltage is applied to a pn junction formed by first underlayer 16 and drift layer 14, specifically, when the electric potential of drain electrode 34 becomes higher than that of source electrode 32, a depletion layer expands in drift layer 14. This can increase the withstand voltage of nitride semiconductor device 10.

Second underlayer 18 is provided above first underlayer 16. Second underlayer 18 is made of an insulating or semi-insulating nitride semiconductor. Second underlayer 18 is, for example, an undoped GaN film having a thickness of 200 nm. Second underlayer 18 is provided in contact with first underlayer 16.

It should be noted that the expression undoped used herein means that the layer is not doped with a dopant, such as silicon (Si) or magnesium (Mg), that changes the polarity of GaN to the n-type or the p-type. In the embodiment, although second underlayer 18 is doped with carbon, second underlayer 18 can be regarded as an undoped nitride semiconductor. Specifically, second underlayer 18 has a carbon concentration higher than that of first underlayer 16.

Moreover, second underlayer 18 may contain silicon (Si) or oxygen (O) that got into second underlayer 18 during the film formation. In this case, the carbon concentration of second underlayer 18 is, for example, higher than or equal to 3×10¹⁷ cm⁻³ and may be higher than or equal to 1×10¹⁸ cm⁻³. The silicon concentration or the oxygen concentration of second underlayer 18 is, for example, lower than or equal to 5×10¹⁶ cm⁻³ and may be lower than or equal to 2×10¹⁶ cm⁻³.

Here, if nitride semiconductor device 10 does not include second underlayer 18, an n-p-n layered structure, that is, a layered structure including n-type electron supply layer 26 and electron transit layer 24, p-type first underlayer 16, and n-type drift layer 14 is formed between source electrode 32 and drain electrode 34. The layered structure serves as a parasitic bipolar transistor having a parasitic NPN structure.

During the off-state of nitride semiconductor device 10, when a current flows through first underlayer 16, the parasitic bipolar transistor may be switched on, which may decrease the withstand voltage of nitride semiconductor device 10. In this case, an error operation of nitride semiconductor device 10 tends to occur.

Second underlayer 18 suppresses the parasitic NPN structure from being formed. Thus, it is possible to decrease an error operation of nitride semiconductor device 10 due to the formation of the parasitic NPN structure. It should be noted that if a current flowing through first underlayer 16 is sufficiently suppressed, nitride semiconductor device 10 need not include second underlayer 18.

Third underlayer 20 is provided above second underlayer 18. Third underlayer 20 is, for example, an Al_{0.2}Ga_{0.8}N film having a thickness of 20 nm. Third underlayer 20 is provided in contact with second underlayer 18.

Third underlayer 20 suppresses a p-type impurity such as Mg from spreading from first underlayer 16. If Mg spreads into a channel in electron transit layer 24, the carrier concentration of two-dimensional electron gas 40 may decrease, which may increase the on-resistance. It should be noted that the spread degree of Mg differs also depending on, for example, epitaxial growth conditions. Thus, if the spread of Mg is suppressed, nitride semiconductor device 10 need not include third underlayer 20.

Moreover, third underlayer 20 may have the function of supplying electrons to the channel formed at the interface between electron transit layer 24 and electron supply layer 26. For instance, third underlayer 20 has a larger band gap than electron supply layer 26.

Gate opening 22 is an example of a first opening passing through first underlayer 16 and reaching drift layer 14. Specifically, gate opening 22 extends from the top surface of third underlayer 20, passes through third underlayer 20, second underlayer 18, and first underlayer 16 in the stated order, and reaches drift layer 14. Bottom surface 22a of gate opening 22 is a portion of the top surface of drift layer 14. In the embodiment, as illustrated in FIG. 2, bottom surface 22a of gate opening 22 is below the interface between drift layer 14 and first underlayer 16.

In the embodiment, the opening area of gate opening 22 increases in the direction away from substrate 12. Specifically, side wall surface 22b of gate opening 22 is inclined relative to first main surface 12a (an x-y plane) of substrate 12. A cross-sectional shape of gate opening 22 is, for example, an inverted trapezoid, more specifically, an inverted isosceles trapezoid.

Electron transit layer 24 is an example of a third nitride semiconductor layer provided along the inner surface of gate opening 22 and at a portion that is outside gate opening 22 and above first underlayer 16. Specifically, electron transit layer 24 is provided along the top surface of third underlayer 20 and side wall surface 22b and bottom surface 22a of gate opening 22.

As illustrated in FIG. 3, electron transit layer 24 includes bottom portion 24a, outer edge portion 24b, and side wall portion 24c.

Bottom portion 24a is a portion provided along bottom surface 22a of gate opening 22. The bottom surface and top surface of bottom portion 24a are parallel to each other, and bottom portion 24a has a practically uniform thickness. The bottom surface of bottom portion 24a is in contact with drift layer 14 at bottom surface 22a of gate opening 22, and the top surface of bottom portion 24a is in contact with electron supply layer 26.

Outer edge portion 24b is a portion provided outside gate opening 22. Specifically, in a plan view, outer edge portion 24b extends from the upper end of side wall surface 22b of gate opening 22 to the upper end of side wall surface 30b of source opening 30. The bottom surface and top surface of outer edge portion 24b are parallel to each other, and outer edge portion 24b has a practically uniform thickness. The bottom surface of outer edge portion 24b is in contact with third underlayer 20, and the top surface of outer edge portion 24b is in contact with electron supply layer 26.

Side wall portion 24c is a portion provided along side wall surface 22b of gate opening 22. In the embodiment, since side wall surface 22b is inclined relative to first main surface 12a, side wall portion 24c is also inclined. The bottom surface of side wall portion 24c is in contact with the respective side surfaces of third underlayer 20, second underlayer 18, and first underlayer 16 at side wall surface 22b of gate opening 22. The top surface of side wall portion 24c is in contact with electron supply layer 26. It should be noted that the bottom surface and top surface of side wall portion 24c are respectively an inclined plane on the lower side and an inclined plane on the upper side among the surfaces of side wall portion 24c.

Electron transit layer 24 has a channel. Specifically, two-dimensional electron gas 40 is generated near the interface between electron transit layer 24 and electron supply layer 26. Two-dimensional electron gas 40 functions as the channel of electron transit layer 24. In FIGS. 2 and 3, two-dimensional electron gas 40 is schematically indicated by the dashed line. Electron transit layer 24 is, for example, an undoped GaN film. Alternatively, electron transit layer 24 may be doped with, for example, Si to change electron transit layer 24 into an n-type conductivity layer.

In the embodiment, the layer thickness of electron transit layer 24 differs depending on the portion. Specifically, layer thickness T1 (the thickness in the Z-axis direction) of bottom portion 24a in a direction perpendicular to first main surface 12a of substrate 12 is less than layer thickness T2 (the thickness in the Z-axis direction) of outer edge portion 24b in the direction perpendicular to first main surface 12a. For instance, layer thickness T1 of bottom portion 24a is 20 nm, and layer thickness T2 of outer edge portion 24b is 100 nm. It should be noted that the above values of layer thickness T1 and layer thickness T2 are mere examples. For instance, the ratio of layer thickness T1 of bottom portion 24a to layer thickness T2 of outer edge portion 24b is within the range from 0.1 times to 0.5 times of layer thickness T2, inclusive, and may be within the range from 0.1 times to 0.2 times of layer thickness T2, inclusive.

Bottom portion 24a is a portion through which a current between the source and the drain flows in the Z-axis direction between two-dimensional electron gas 40 and drift layer 14. Since bottom portion 24a has a thin film thickness, low on-resistance can be achieved.

It should be noted that when for instance the width (the length in the X-axis direction) of bottom surface 22a is small, the following situation may occur: at the portion along bottom surface 22a, electron transit layer 24 hardly includes a portion having a practically uniform layer thickness. In this case, in electron transit layer 24, the value of layer thickness T1 of bottom portion 24a can be regarded as the smallest value within the range in which bottom portion 24a overlaps bottom surface 22a in the plan view.

Alternatively, layer thickness T1 of bottom portion 24a may be regarded as the layer thickness of electron transit layer 24 at the center position of gate opening 22 or bottom surface 22a in the X-axis direction. Likewise, layer thickness T2 of outer edge portion 24b may be regarded as the layer thickness of electron transit layer 24 at the center position in the X-axis direction between the upper end of side wall surface 22b of gate opening 22 and the upper end of side wall surface 30b of source opening 30.

Moreover, in the embodiment, layer thickness T3 (the thickness in the x-axis direction) of side wall portion 24c in a direction parallel to first main surface 12a of substrate 12 is greater than layer thickness T2 (the thickness in the Z-axis direction) of outer edge portion 24b in the direction perpendicular to first main surface 12a of substrate 12. For instance, layer thickness T3 of side wall portion 24c is 200 nm, and layer thickness T2 of outer edge portion 24b is 100 nm. It should be noted that the above values of layer thickness T2 and layer thickness T3 are mere examples.

This can increase the distance between side wall portion 24c and p-type second underlayer 18, which can suppress the carrier concentration of electron transit layer 24 from decreasing. Thus, it is possible to decrease the on-resistance of nitride semiconductor device 10.

It should be noted that electron transit layer 24 is an example of a first regrowth layer formed by crystal regrowth after gate opening 22 is formed. Moreover, although not illustrated in the figures, in the embodiment, as a second regrowth layer, an AlN film having a thickness of around 1 nm is provided between electron transit layer 24 and electron supply layer 26. The AlN film can suppress alloy scattering and improve the channel mobility. It should be noted that the AlN film need not be provided, and electron transit layer 24 and electron supply layer 26 may be directly in contact with each other. It should be noted that electron supply layer 26 is an example of a third regrowth layer formed by crystal regrowth after electron transit layer 24 is formed.

Electron supply layer 26 is an example of a fourth nitride semiconductor layer provided along the inner surface of gate opening 22 and at a portion that is outside gate opening 22 and above first underlayer 16. It should be noted that electron transit layer 24 and electron supply layer 26 are provided in the stated order from the side on which substrate 12 is present. Electron supply layer 26 is provided with an approximately uniform thickness. Electron supply layer 26 is, for example, an undoped Al_{0.2}Ga_{0.8}N film having a thickness of 50 nm.

Electron supply layer 26 supplies electrons to the channel formed in electron transit layer 24. It should be noted that as described above, in the embodiment, third underlayer 20 also has the function of supplying electrons. Although each of electron supply layer 26 and third underlayer 20 is made of AlGaN, the Al composition ratio of each layer is not limited to a particular Al composition ratio. For instance, the Al composition ratio of electron supply layer 26 may be 20%, and the Al composition ratio of third underlayer 20 may be 25%.

It should be noted that the composition ratio of the group III elements of a nitride semiconductor (layer) indicates the ratio of the number of the atoms of a target group III element out of a plurality of group III elements included in the nitride semiconductor. For instance, when the nitride semiconductor layer is made of AlₐGa_{b}N (a+b=1, a≥0, b≥0), the Al composition ratio of the nitride semiconductor layer can be expressed as a/(a+b). Likewise, the Ga composition ratio of the nitride semiconductor layer is expressed as b/(a+b).

Gate electrode 28 is so provided as to be positioned above electron supply layer 26 and cover gate opening 22. In the embodiment, gate electrode 28 having a shape following the top surface of electron supply layer 26 and an approximately uniform thickness is provided in contact with the top surface of electron supply layer 26.

Gate electrode 28 is made using a conductive material such as a metal. For instance, gate electrode 28 is made using palladium (Pd). It should be noted that a material to be Schottky-connected to an n-type semiconductor can be used as a material of gate electrode 28. For instance, a nickel (Ni)-based material, tungsten silicide (WSi), or gold (Au) can be used.

In the plan view, gate electrode 28 is spaced apart from source electrode 32 to avoid contact with source electrode 32. Specifically, as illustrated in (b) in FIG. 1, in the plan view, gate electrode 28 surrounds source electrode 32. More specifically, gate electrode 28 is formed into a shape of a plate having openings corresponding to hexagonal source electrodes 32.

In the embodiment, in the plan view, the end of gate electrode 28 is closer to source electrode 32 than the end of gate opening 22 is. That is, in the plan view, the distance between the end of gate electrode 28 and source electrode 32 is less than the distance between the end of gate opening 22 and source electrode 32. Specifically, in the plan view, gate opening 22 is provided inside gate electrode 28. In other words, gate electrode 28 is provided directly above the upper end of side wall surface 22b of gate opening 22.

Source opening 30 is an example of a second opening that is spaced apart from gate electrode 28, passes through electron supply layer 26 and electron transit layer 24, and reaches first underlayer 16. Specifically, source opening 30 passes through electron supply layer 26, electron transit layer 24, third underlayer 20, and second underlayer 18 in the stated order, and reaches first underlayer 16. In the embodiment, as illustrated in FIG. 2, bottom surface 30a of source opening 30 is a portion of the top surface of first underlayer 16. Bottom surface 30a is below the interface between first underlayer 16 and second underlayer 18. In the plan view, source opening 30 is spaced apart from gate opening 22.

As illustrated in FIG. 2, the opening area of source opening 30 is approximately uniform. Specifically, side wall surface 30b of source opening 30 is approximately parallel to a thickness direction of substrate 12 (the z-axis direction). For instance, source opening 30 has a rectangular cross-sectional shape. Alternatively, the cross-sectional shape of source opening 30 may be an inverted trapezoid as with gate opening 22.

In the embodiment, as illustrated in (b) in FIG. 1, the opening shape, that is, the plan view shape of source opening 30 is a regular hexagon. The distance between source opening 30 and gate electrode 28 surrounding the perimeter of source opening 30 is approximately constant. Side wall surface 30b of source opening 30 has a (1-100) plane. Here, the (1-100) plane is a collective term for the (1-100) plane and planes equivalent to the (1-100) plane.

Source electrode 32 is provided inside source opening 30. Specifically, source electrode 32 is so provided as to fill source opening 30.

Source electrode 32 is electrically connected to first underlayer 16. Specifically, source electrode 32 is in contact with the end faces of electron supply layer 26, electron transit layer 24, third underlayer 20, and second underlayer 18. Source electrode 32 makes an ohmic connection with electron transit layer 24 and electron supply layer 26.

Source electrode 32 is made using a conductive material such as a metal. A material to make an ohmic connection with an n-type semiconductor layer, such as a layered structure of Ti and Al can be used as a material of source electrode 32.

Since source electrode 32 is connected to first underlayer 16, it is possible to fix the electric potential of p-type first underlayer 16, which can stabilize operation of nitride semiconductor device 10.

Moreover, Al is Schottky-connected to first underlayer 16 made of a p-type nitride semiconductor. Thus, a lower portion of source electrode 32 may include a large-work-function metal material, such as Pd or Ni, that has low contact resistance to the p-type nitride semiconductor. This can further stabilize the electric potential of first underlayer 16.

Drain electrode 34 is provided on the same side as the second main surface 12b side of substrate 12. Specifically, drain electrode 34 is provided in contact with second main surface 12b. Drain electrode 34 is made using a conductive material such as a metal. As with the material of source electrode 32, a material to make an ohmic connection with an n-type semiconductor layer, such as Ti/Al can be used as a material of drain electrode 34.

Gate electrode pad 36 is electrically connected to gate electrode 28. Gate electrode pad 36 is, for example, provided above gate electrode 28. In the embodiment, gate electrode 28 is formed into a shape of a plate. As such, as illustrated in (a) in FIG. 1, gate electrode pad 36 is formed only at a portion of nitride semiconductor device 10 in the plan view. A power supply for controlling gate electrode 28 is connected to gate electrode pad 36.

Source electrode pad 38 is electrically connected to source electrodes 32. Source electrode pad 38 is above source electrode 32. In the embodiment, source electrodes 32 are hexagonal-island-shaped. Thus, in the plan view of nitride semiconductor device 10, in a most area except gate electrode pad 36, source electrode pad 38 is so provided as to cover source electrodes 32.

As described above, in nitride semiconductor device 10 according to the embodiment, the interface between electron transit layer 24 and electron supply layer 26 serves as an AlGaN/GaN heterointerface. Thus, two-dimensional electron gas 40 is generated in electron transit layer 24, thereby forming the channel. Two-dimensional electron gas 40 has a high carrier concentration, which increases the channel mobility and decreases the on-resistance. Because of the thin film thickness of bottom portion 24a, where the current between the source and the drain flows in the Z-axis direction between two-dimensional electron gas 40 and drift layer 14, it is possible to further decrease the on-resistance.

[Fabrication method]

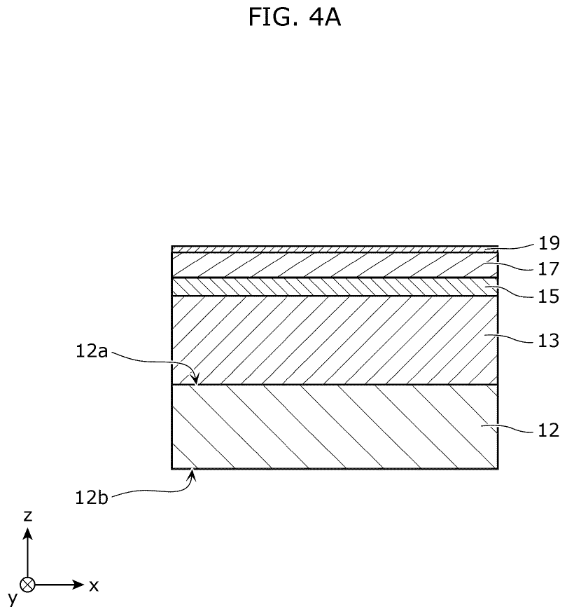

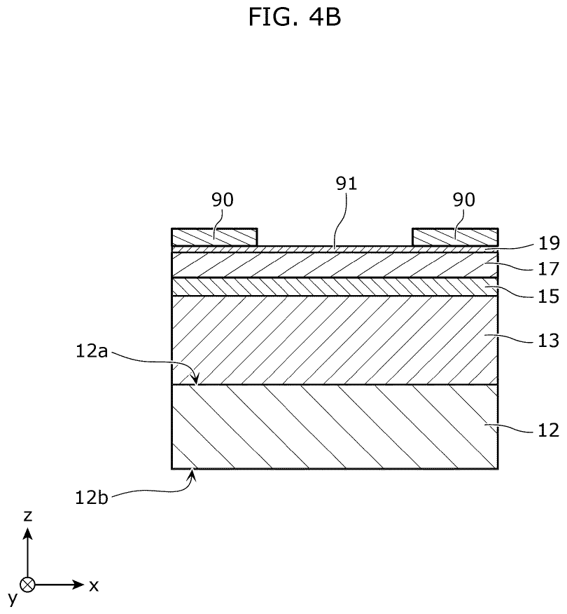

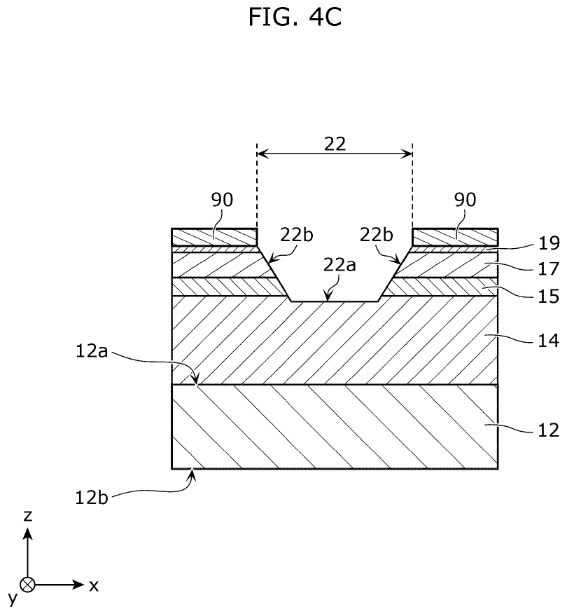

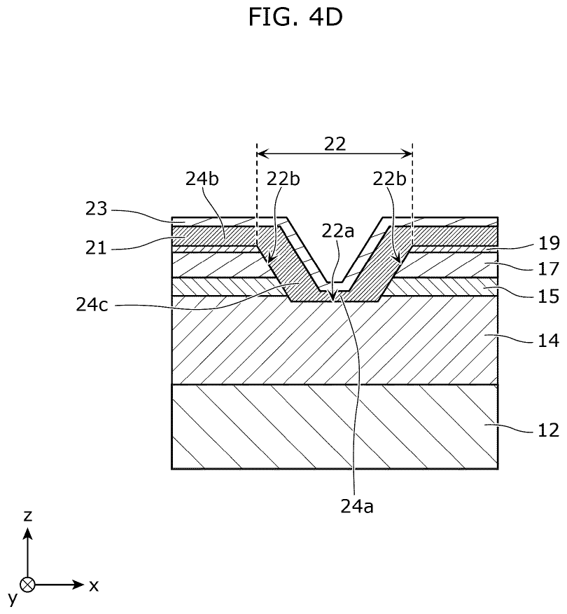

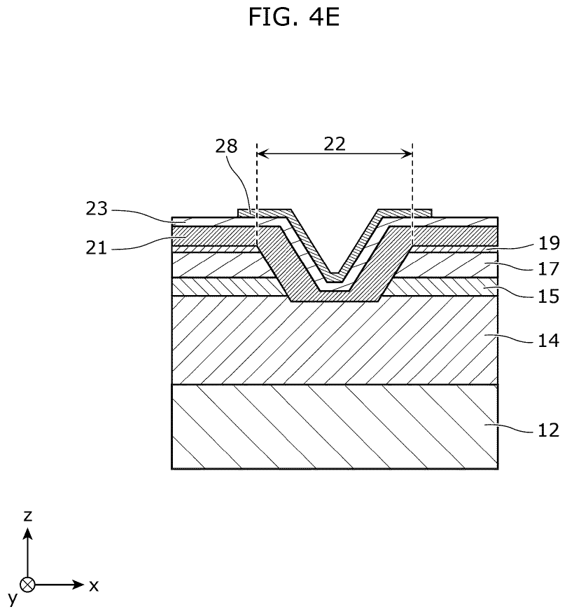

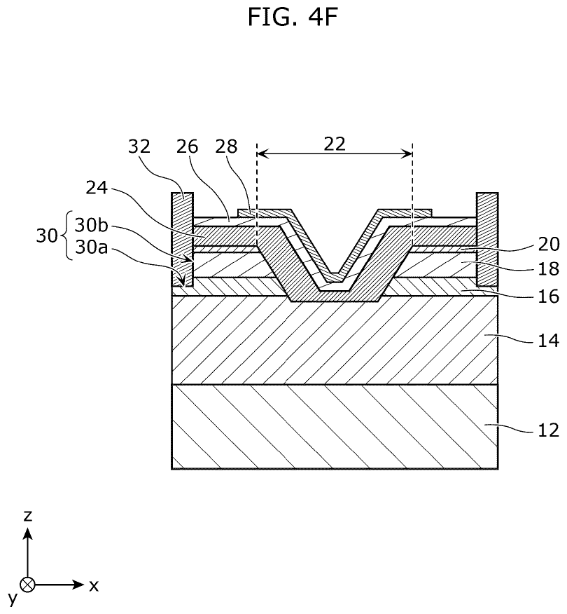

Next, a fabrication method for fabricating nitride semiconductor device 10 according to the embodiment is described with reference to FIGS. 4A to 4F. FIGS. 4A to 4F are cross-sectional views illustrating the processes of the fabrication method for fabricating nitride semiconductor device 10 according to the embodiment.

Hereinafter, a case where the nitride semiconductor layers of nitride semiconductor device 10 are formed by metal organic vapor phase epitaxy (MOVPE) is described. It should be noted that a method for forming the nitride semiconductor layers is not limited to MOVPE. For instance, the nitride semiconductor layers may be formed by molecular beam epitaxy (MBE).

Moreover, an n-type nitride semiconductor is formed by adding, for example, silicon (Si). A p-type nitride semiconductor is formed by adding magnesium (Mg). It should be noted that an n-type impurity and a p-type impurity are not limited to the above examples.

First, the process of forming a first nitride semiconductor layer and a p-type second nitride semiconductor layer in the stated order above a substrate is performed. Specifically, n-type GaN substrate 12 whose first main surface 12a is the (0001) plane, that is, the c-plane is prepared. As illustrated in FIG. 4A, n-type GaN film 13 to which Si has been added as an n-type impurity, p-type GaN film 15 to which Mg has been added as a p-type impurity, undoped GaN film 17, and undoped AlGaN film 19 made of undoped Al_{0.2}Ga_{0.8}N are formed in the stated order above first main surface 12a of substrate 12.

Here, n-type GaN film 13 is an example of the first nitride semiconductor layer, and p-type GaN film 15 is an example of the second nitride semiconductor layer. It should be noted that n-type GaN film 13, p-type GaN film 15, undoped GaN film 17, and undoped AlGaN film 19 are patterned into predetermined shapes to respectively become drift layer 14, first underlayer 16, second underlayer 18, and third underlayer 20 illustrated in FIG. 2.

The layers have thicknesses and carrier concentrations as described below, for example. N-type GaN film 13 has a thickness of 8 μm and a carrier concentration of 1×10¹⁶ cm⁻³. P-type GaN film 15 has a thickness of 400 nm and a carrier concentration of 1×10¹⁷ cm⁻³. Undoped GaN film 17 has a thickness of 200 nm. Undoped AlGaN film 19 has a thickness of 20 nm. It should be noted that the above numerical values are mere examples.

The process of forming a first opening passing through the second nitride semiconductor layer and reaching the first nitride semiconductor layer is performed. Specifically, first, as illustrated in FIG. 4B, a resist is applied to undoped AlGaN film 19, the applied resist is patterned by photolithography to form resist mask 90. Resist mask 90 is a mask for forming gate opening 22 and has opening 91 that conforms to the plan-view shape of gate opening 22.

Next, as illustrated in FIG. 4C, gate opening 22 is formed by dry etching. Gate opening 22 is an example of the first opening, and passes through undoped AlGaN film 19, undoped GaN film 17, and p-type GaN film 15. Drift layer 14 is formed by removing a surface portion of n-type GaN film 13. Drift layer 14 is exposed in gate opening 22. Here, bottom surface 22a of gate opening 22 is parallel to first main surface 12a of substrate 12. Side wall surface 22b of gate opening 22 is inclined relative to bottom surface 22a with a predetermined angle of inclination. The angle of inclination falls within the range from 20 degrees to 80 degrees, inclusive, for example.

Then, the process of forming a third nitride semiconductor layer and a fourth nitride semiconductor layer in the stated order along the inner surface of the first opening and a portion that is outside the first opening and above the second nitride semiconductor layer is performed. Specifically, after resist mask 90 is removed, as illustrated in FIG. 4D, undoped GaN film 21, an undoped AlN film (not illustrated), and undoped AlGaN film 23 are formed in the stated order by MOVPE on the entire surface of opening 22 along the shape of gate opening 22.

Here, undoped GaN film 21 is an example of the third nitride semiconductor layer, and undoped AlGaN film 23 is an example of the fourth nitride semiconductor layer. Undoped GaN film 21 and undoped AlGaN film 23 are patterned into predetermined shapes to respectively become electron transit layer 24 and electron supply layer 26.

In the process of forming the third nitride semiconductor layer, the third nitride semiconductor layer is formed by epitaxial growth under the condition that facilitates growth more in a direction parallel to a main surface of the substrate than in a direction perpendicular to the main surface. Specifically, in forming undoped GaN film 21 to be electron transit layer 24, epitaxial growth is performed under the condition that facilitates growth more in the direction (the X-axis direction and the Y-axis direction) parallel to first main surface 12a than in the direction (the Z-axis direction) perpendicular to first main surface 12a of substrate 12. The condition is a condition that facilitates the migration of source materials during the epitaxial growth. This enables bottom portion 24a, outer edge portion 24b, and side wall portion 24c of electron transit layer 24 to have different layer thicknesses.

Typically, film formation proceeds in the Z-axis direction at the portion along bottom surface 22a of gate opening 22, and film formation proceeds in the X-axis direction at the portion along side wall surface 22b of gate opening 22. Here, facilitation of the migration enables the source materials that have reached bottom surface 22a of gate opening 22 to actively move, which makes it easier for the source materials to be taken into the portion along side wall surface 22b of gate opening 22. Thus, film formation in the X-axis direction from side wall surface 22b of gate opening 22 is facilitated, which increases the layer thickness in the X-axis direction. Meanwhile, since the portion along bottom surface 22a of gate opening 22 has a shortage of source materials, film formation in the Z-axis direction is suppressed at bottom surface 22a of gate opening 22. This can decrease the layer thickness of bottom portion 24a along bottom surface 22a of gate opening 22 without decreasing the layer thickness of outer edge portion 24b outside gate opening 22.

A condition that facilitates the migration is to raise the film formation temperature. According to test results, when the film formation temperature of undoped GaN film 21 is 1080 degrees Celsius, layer thickness T2 of outer edge portion 24b is 100 nm, layer thickness T1 of bottom portion 24a is 150 nm, and layer thickness T3 of side wall portion 24c is 100 nm. By contrast, when a film formation temperature of electron transit layer 24 is 1100 degrees Celsius, which is 20 degrees Celsius higher than 1080 degrees Celsius, layer thickness T2 of outer edge portion 24b is 100 nm, layer thickness T1 of bottom portion 24a is 20 nm, and layer thickness T3 of side wall portion 24c is 200 nm. This shows that layer thickness T1 of bottom portion 24a of electron transit layer 24 can be decreased by raising the formation temperature and facilitating the migration.

For instance, the film formation temperature of undoped GaN film 21 is at least 1100 degrees Celsius and at most 1200 degrees Celsius. The film formation temperature range exemplified here is a mere example. For instance, the lower limit of the film formation temperature may be 1100 degrees Celsius, 1110 degrees Celsius, 1120 degrees Celsius, 1130 degrees Celsius, 1140 degrees Celsius, and 1150 degrees Celsius. The upper limit of the film formation temperature may be 1200 degrees Celsius, 1190 degrees Celsius, 1180 degrees Celsius, 1170 degrees Celsius, 1160 degrees Celsius, and 1150 degrees Celsius. Raising the film formation temperature facilitates crystal growth in the X-axis direction, which can further decrease layer thickness T1 of bottom portion 24a. Meanwhile, by setting the film formation temperature not too high, decomposition of GaN can be suppressed and a good surface condition can be obtained, which can enhance the reliability of nitride semiconductor device 10.

Moreover, another condition that facilitates the migration is to increase a V/III ratio. A V/III ratio is a mole ratio per unit time of a group V source material to a group III source material, and is expressed as (the molar quantity of the group V source material)/(the molar quantity of the group III source material). For instance, the feed amount of ammonia, which is a group V source material, is set constant, and the feed amount of trimethylgallium, which is a group III source material, is decreased. Also in this way, it is possible to facilitate the migration and obtain effects similar to those obtained by raising the film formation temperature.

For instance, the V/III ratio in forming undoped GaN film 21 is at least 1000 and at most 50000. The V/III ratio may be at least 5000 and at most 20000. It should be noted that the V/III ratio ranges exemplified here are mere examples. For instance, the lower limit of the V/III ratio may be 1000, 5000, 7000, and 10000. Moreover, the upper limit of the V/III ratio may be 50000, 40000, 30000, and 20000. Increasing the V/III ratio facilitates crystal growth in the X-axis direction, which can further decrease layer thickness T1 of bottom portion 24a. Meanwhile, the film formation time can be shortened by setting the V/III ratio not too high, which can enhance the productivity.

Both the film formation temperature and the V/III ratio may be adjusted to facilitate the migration.

It should be noted that the undoped AlN film has a thickness of 1 nm. Undoped AlGaN film 23 has a thickness of 50 nm. It should be noted that the above numerical values are mere examples.

Then, the process of forming a gate electrode above the fourth nitride semiconductor layer such that the gate electrode covers the first opening is performed. Specifically, a gate metal film made of Pd is so formed as to cover gate opening 22 by, for example, vapor deposition or sputtering. As illustrated in FIG. 4E, gate electrode 28 is formed by patterning the formed gate metal film.

Furthermore, the process of forming a source electrode at a position apart from the gate electrode is performed. Specifically, source opening 30 is formed at a position apart from gate electrode 28, source opening 30 passing through undoped AlGaN film 23, an undoped AlN film (not illustrated), undoped GaN film 21, undoped AlGaN film 19, and undoped GaN film 17 and reaching p-type GaN film 15. As with gate opening 22, source opening 30 is formed by photolithography and dry etching. As illustrated in FIG. 4F, electron supply layer 26, electron transit layer 24, third underlayer 20, second underlayer 18, and first underlayer 16 are formed by patterning undoped AlGaN film 23, undoped GaN film 21, undoped AlGaN film 19, undoped GaN film 17, and p-type GaN film 15.

Then, by, for example, vapor deposition or sputtering, a source metal film made of Ti and Au is so formed as to fill source opening 30, and the formed source metal film is patterned into source electrode 32.

Furthermore, the process of forming a drain electrode on the opposite side of the substrate from the first nitride semiconductor layer is performed. Specifically, a drain metal film made of Ti and Al is formed on second main surface 12b of substrate 12 by, for example, vapor deposition or sputtering, and the formed drain metal film is patterned as necessary, thereby forming drain electrode 34.

Nitride semiconductor device 10 illustrated in FIG. 2 is formed through the above processes.

It should be noted that after gate electrode 28 and source electrode 32 are formed, an insulator film is formed, and contact holes for exposing a portion of each of a plurality of source electrodes 32 and a portion of gate electrode 28 are formed in the formed insulator film. Then, a metal film is formed and patterned into gate electrode pad 36 and source electrode pad 38.

### Variation

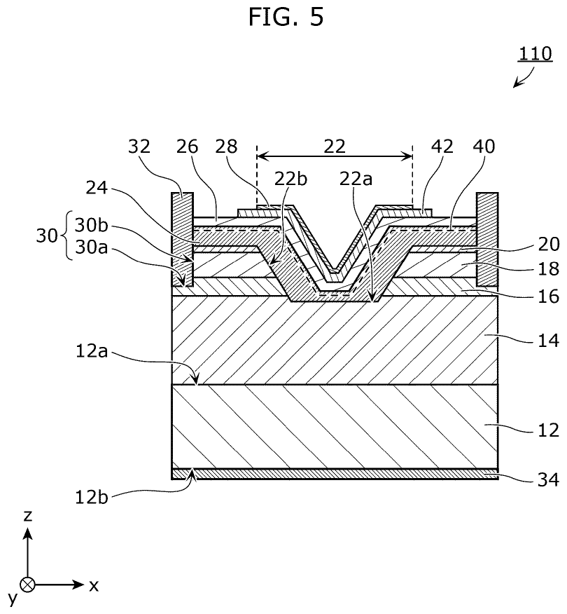

Hereinafter, a variation of nitride semiconductor device 10 according to the embodiment is described with reference to FIG. 5.

FIG. 5 is a cross-sectional view of nitride semiconductor device 110 according to the variation. As illustrated in FIG. 5, nitride semiconductor device 110 includes threshold control layer 42 as a difference from nitride semiconductor device 10 illustrated in FIG. 2. Hereinafter, the differences from the embodiment are focused on, and explanations of common points are omitted or simplified.

Threshold control layer 42 is an example of a p-type fifth nitride semiconductor layer provided between gate electrode 28 and electron supply layer 26. Threshold control layer 42 is provided above electron supply layer 26 and is in contact with electron supply layer 26 and gate electrode 28.

In the variation, in a plan view of substrate 12, the end of threshold control layer 42 is closer to source electrode 32 than the end of gate electrode 28 is. Threshold control layer 42 and source electrode 32 are spaced apart from each other and are not in contact with each other.

Threshold control layer 42 is, for example, a p-type Al_{0.2}Ga_{0.8}N nitride semiconductor layer having a thickness of 100 nm and a carrier concentration of 1×10¹⁷ cm⁻³. A film is formed by MOVPE, following the formation of undoped AlGaN film 23 to be electron supply layer 26, and the formed film is patterned. In this way, threshold control layer 42 is formed.

In the variation, threshold control layer 42 increases the electric potential of the conduction band edge of a channel portion. This enables nitride semiconductor device 110 to have a large threshold voltage. Accordingly, nitride semiconductor device 110 can be achieved as a normally-off FET.

### Other Embodiments

Although the nitride semiconductor devices according to one or more aspects is described according to the embodiment, the present disclosure is not limited to the embodiment. The scope of the present disclosure may also encompass embodiments obtained by adding, to the embodiment, various modifications envisioned by those skilled in the art, and embodiments obtained by combining elements in different embodiments, as long as the resultant embodiments do not depart from the scope of the present disclosure.

For instance, in a plan view, the end of gate electrode 28 may correspond to the end of gate opening 22. Alternatively, in the plan view, gate electrode 28 may be provided inside gate opening 22.

Moreover, for instance, the plan view shape of each of source electrode 32 and source opening 30 is not limited to a hexagon, and may be a rectangular elongated in one direction (the Y-axis direction, for example). In this case, in the plan view, a plurality of source electrodes 32 are arranged in stripes. The plan view shape of the portion, that is positioned between adjacent source electrodes 32, of each of gate electrode 28 and of gate opening 22 is also an elongated rectangle, and gate electrode 28 and gate openings 22 are arranged in stripes.

Moreover, in the above embodiment, source opening 30 reaching first underlayer 16 is provided as a non-limiting example. For instance, source opening 30 may be an opening reaching electron transit layer 24, and source electrode 32 may be connected to electron transit layer 24 and need not be connected to first underlayer 16.

Moreover, in the above embodiments, various changes, replacement, addition, and omission can be performed within the scope of the claims or equivalent range thereof.

### INDUSTRIAL APPLICABILITY

The present disclosure can be used as a nitride semiconductor device with low on-resistance, and can be used as a power transistor used in, for example, a power supply circuit of consumer equipment such as a television.

1. A nitride semiconductor device comprising:
a substrate;
a first nitride semiconductor layer provided above the substrate;
a second nitride semiconductor layer of p-type conductivity provided above the first nitride semiconductor layer;
a third nitride semiconductor layer and a fourth nitride semiconductor layer that are provided along an inner surface of a first opening and at a portion that is outside the first opening and above the second nitride semiconductor layer, the third nitride semiconductor layer and the fourth nitride semiconductor layer being provided in stated order from a side on which the substrate is present, the first opening passing through the second nitride semiconductor layer and reaching the first nitride semiconductor layer;
a gate electrode provided above the fourth nitride semiconductor layer;
a source electrode spaced apart from the gate electrode; and
a drain electrode provided on an opposite side of the substrate from the first nitride semiconductor layer, wherein
the third nitride semiconductor layer includes:
a bottom portion provided along a bottom surface of the first opening; and
an outer edge portion provided outside the first opening, and
a layer thickness of the bottom portion in a direction perpendicular to a main surface of the substrate is less than a layer thickness of the outer edge portion in the direction perpendicular to the main surface.

2. The nitride semiconductor device according to claim 1, wherein
the third nitride semiconductor layer includes a side wall portion provided along a side wall surface of the first opening, and
a layer thickness of the side wall portion in a direction parallel to the main surface is greater than the layer thickness of the outer edge portion in the direction perpendicular to the main surface.

3. The nitride semiconductor device according to claim 1, further comprising:
a fifth nitride semiconductor layer of the p-type conductivity provided between the gate electrode and the fourth nitride semiconductor layer.

4. The nitride semiconductor device according to claim 1, wherein
at a position apart from the gate electrode, the source electrode is provided inside a second opening passing through the fourth nitride semiconductor layer and the third nitride semiconductor layer and reaching the second nitride semiconductor layer.

5. The nitride semiconductor device according to claim 1, wherein
in a plan view of the substrate, a distance between an end of the gate electrode and the source electrode is less than a distance between an end of the first opening and the source electrode.

6. A fabrication method for fabricating a nitride semiconductor device, the fabrication method comprising:
a process of forming a first nitride semiconductor layer and a second nitride semiconductor layer of p-type conductivity above a substrate in stated order;
a process of forming a first opening passing through the second nitride semiconductor layer and reaching the first nitride semiconductor layer;
a process of forming a third nitride semiconductor layer and a fourth nitride semiconductor layer in stated order along an inner surface of the first opening and at a portion that is outside the first opening and above the second nitride semiconductor layer;
a process of forming a gate electrode above the fourth nitride semiconductor layer;
a process of forming a source electrode at a position apart from the gate electrode; and
a process of forming a drain electrode on an opposite side of the substrate from the first nitride semiconductor layer, wherein
in the process of forming the third nitride semiconductor layer, the third nitride semiconductor layer is formed by epitaxial growth under a condition that facilitates growth more in a direction parallel to a main surface of the substrate than in a direction perpendicular to the main surface.

7. The fabrication method for fabricating the nitride semiconductor device according to claim 6, wherein
the condition includes that a film formation temperature is higher than or equal to 1100 degrees Celsius.

8. The fabrication method for fabricating the nitride semiconductor device according to claim 6, wherein
the condition includes that a V/III ratio of feed materials is greater than or equal to 1000.
